(19) United States
(12) Patent Application Publication
(10) Pub. No.: US 2026/0363042 A1
(43) Pub. Date: Nov. 12, 2026

(54) ALD TUNGSTEN FILL WITH BOOSTED THERMAL INHIBITION

(71) Applicant: Lam Research Corporation, Fremont, CA (US)

(72) Inventors: Yu Pan, San Jose, CA (US); Ying Qin, San Jose, CA (US); Xiaolan Ba, Fremont, CA (US); Zizhuo Zhang, San Jose, CA (US); Juwen Gao, San Jose, CA (US); Ravi Vellanki, San Jose, CA (US); Andrew Paul Eib, Campbell, CA (US)

(21) Appl. No.: 19/139,212

(22) PCT Filed: Nov. 30, 2023
(86) PCT No.: PCT/US2023/081921

§ 371 Date: Jun. 13, 2025

Related U.S. Application Data
(60) Provisional application No. 63/387,886, filed on Dec. 16, 2022.

(51) Int. Cl. H10W 20/00; C23C 16/455; H10B 41/20; H10B 43/20; H10P 14/40; H10P 14/43

(52) U.S. Cl. CPC H10W 20/0261; C23C 16/45548; C23C 16/45557; C23C 16/45561; C23C 16/45565; H10B 41/20; H10B 43/20; H10P 14/412; H10P 14/432; H10W 20/034; H10W 20/045; H10W 20/057

(57) ABSTRACT

Methods of filling wordline features of 3-D NAND structures with tungsten include treating a conformal tungsten with nitrogen trifluoride (NF₃) in combination with a booster gas. The NF₃ treatment is preferential to the openings of the wordline features relative to the interiors of the wordline features. The treatment inhibits subsequent deposition on the treated surfaces. Subsequent deposition is selective to the interior of the wordline features allowing non-conformal, inside-out deposition. The NF₃ may be delivered from a gas zone that is isolated from tungsten deposition gases and the booster gas. The NF₃ may be delivered from a charge volume to facilitate top-to-bottom uniform treatment of a 3D NAND structure. Apparatuses for filling wordline features include separate gas zones and individually controlled stations.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Deposition of materials including tungsten-containing materials is an integral part of many semiconductor fabrication processes. These materials may be used for horizontal interconnects, vias between adjacent metal layers, and contacts between metal layers and devices. As devices shrink and more complex patterning schemes are utilized in the industry, deposition of tungsten films becomes a challenge. The continued decrease in feature size and film thickness bring various challenges including high resistivity for thinner films and difficulty in obtaining void-free fill in features. Deposition in complex high aspect ratio structures such as 3D NAND structures is particularly challenging.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect involves a method including: providing a 3-D structure of a partially manufactured semiconductor substrate to a chamber having a chamber pressure of no more than 100 Torr, the 3-D structure including sidewalls, a plurality of openings in the sidewalls leading to a plurality of features having a plurality of interior regions fluidically accessible through the openings to a chamber; depositing a first layer of tungsten within the 3-D structure such that the first layer lines the plurality of features of the 3-D structure; and treating the first layer of tungsten non-conformally with a treatment such that that the treatment is preferentially applied at portions of the first layer of tungsten near the plurality of openings relative to the plurality of interior regions; introducing a booster gas including H₂ to the chamber; and depositing a second layer of tungsten within the 3-D structure on the first layer of tungsten such that the second layer at least partially fills the plurality of interior regions of the 3-D structure; whereby treating the first layer of tungsten non-conformally includes charging a gas including NF₃ to a first charge pressure of least 10 Torr and flowing the gas to the chamber.

In various embodiments, the booster gas further includes argon.

In various embodiments, the booster gas further includes nitrogen.

In various embodiments, the booster gas is introduced during the treating of the first layer of tungsten.

In various embodiments, the booster gas is introduced before the treating of the first layer of tungsten and after depositing the first layer of tungsten.

In various embodiments, the booster gas is introduced after the treating of the first layer of tungsten and before depositing the second layer of tungsten.

In various embodiments, the method also includes depositing a nucleation layer within the 3-D structure such that nucleation layer lines the plurality of features of the 3-D structure, whereby the booster gas is introduced before the treating of the first layer of tungsten, before depositing the first layer of tungsten, and after depositing the nucleation layer. In some embodiments, depositing the nucleation layer takes place at a first station in the chamber and the deposition of the first layer of tungsten, the treatment, and the deposition of the second layer of tungsten takes place in a second station in the chamber.

In various embodiments, the treatment inhibits tungsten deposition.

In various embodiments, depositing a layer of tungsten includes an atomic layer deposition using tungsten hexafluoride (WF₆) and hydrogen (H₂).

In various embodiments, depositing a layer of tungsten includes delivering pulses of a tungsten precursor and hydrogen to the chamber via a showerhead.

In various embodiments, depositing tungsten includes delivering a tungsten precursor and hydrogen to a showerhead via a dual inlet chamber.

In various embodiments, the tungsten precursor and hydrogen are injected at a first inlet of the dual inlet chamber. In some embodiments, the gas including NF₃ is injected at a second inlet of the dual inlet chamber.

In various embodiments, an inert gas is injected in the first inlet of the dual inlet chamber while the NF₃ is injected at the second inlet of the dual inlet chamber.

In various embodiments, the tungsten precursor and hydrogen gas are supplied through a first gas manifold and the NF₃ is supplied through a second gas manifold.

Another aspect involves an apparatus for semiconductor processing, the apparatus including: a first showerhead; a dual inlet chamber having a first inlet, a second inlet, and an outlet fluidly connected to the first showerhead; a first gas zone including a first process gas manifold, the first process gas manifold including: one or more first process gas charge volumes, a first divert valve fluidically connected to the one or more first process gas charge volumes, and a first injection process gas valve fluidically connected to the first divert process gas valve, whereby the first process gas manifold is configured to be fluidically connected to one or more first process gas sources via the one or more first process gas charge volumes; and whereby the first process gas manifold, via the first injection process gas valve, is fluidically connected to the first inlet of the dual inlet chamber; a second gas zone including a second process gas manifold, the second process gas manifold including: one or more second process gas charge volumes, a second divert valve fluidically connected to the one or more second process gas charge volumes, and a second injection process gas valve fluidically connected to the second divert process gas valve, whereby the second process gas manifold is configured to be fluidically connected to one or more second process gas sources via the one or more second process gas charge volumes; and whereby the second process gas manifold, via the second injection process gas valve, is fluidically connected to the second inlet of the dual inlet chamber; a top plate divert manifold, whereby the top plate divert manifold is fluidically connected to the first process gas manifold via the first divert valve; and a gas box divert manifold, whereby the gas box divert manifold is fluidically connected to the second process gas manifold via the second divert valve, whereby the first gas zone is separate from the second gas zone upstream of the dual inlet chamber.

In various embodiments, the method includes a multi-station chamber having a first station including the first showerhead and one or more additional stations, each including a showerhead.

In various embodiments, at least one station of the multi-station chamber is fluidically connected to no more than one gas zone.

In various embodiments, the dual inlet chamber includes an annulus surrounding a main line connected to the outlet. In some embodiments, the second inlet is at a side of the annulus.

These and other aspects are described further below with reference to the drawings.

### BRIEF DESCRIPTION OF THE DRAWINGS

FIG. 1A-1E present different views and aspects of an example 3-D NAND structure.

FIG. 2A-2D are process flow diagrams illustrating certain operations in methods of treating and filling a feature with tungsten for certain disclosed embodiments.

FIGS. 3, 4A, 4B, and 5 are schematic representations of a wordline feature at various stages of treatment and fill with tungsten.

FIG. 6A shows a schematic representation of apparatus that may be used to perform the methods described herein.

FIG. 6B shows a schematic representation of apparatus that may be used to perform the methods described herein.

FIG. 7 shows an example dual inlet chamber and example showerhead.

FIG. 8 shows a top view of an example inhibition gas manifold and process gas manifold.

FIG. 9 is a process flow diagram illustrating certain operations in methods for tungsten deposition.

FIG. 10 shows a schematic of an example process system that may be used to perform the methods described herein.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Provided herein are methods of filling features with tungsten (W). The methods described herein can be used to fill vertical features, such as in tungsten vias, and horizontal features, such as 3-D NAND wordlines.

The methods described herein are performed on a substrate that may be housed in a chamber. The substrate may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods are not limit to semiconductor substrates and may be performed to fill any feature with tungsten.

Substrates may have features such as via or contact holes, which may be characterized by one or more of narrow and/or re-entrant openings, constrictions within the feature, and high aspect ratios. A feature may be formed in one or more of the above described layers. For example, the feature may be formed at least partially in a dielectric layer. In some embodiments, a feature may have an aspect ratio of at least about 2:1, at least about 4:1, at least about 6:1, at least about 10:1, at least about 25:1, or higher. One example of a feature is a hole or via in a semiconductor substrate or a layer on the substrate.

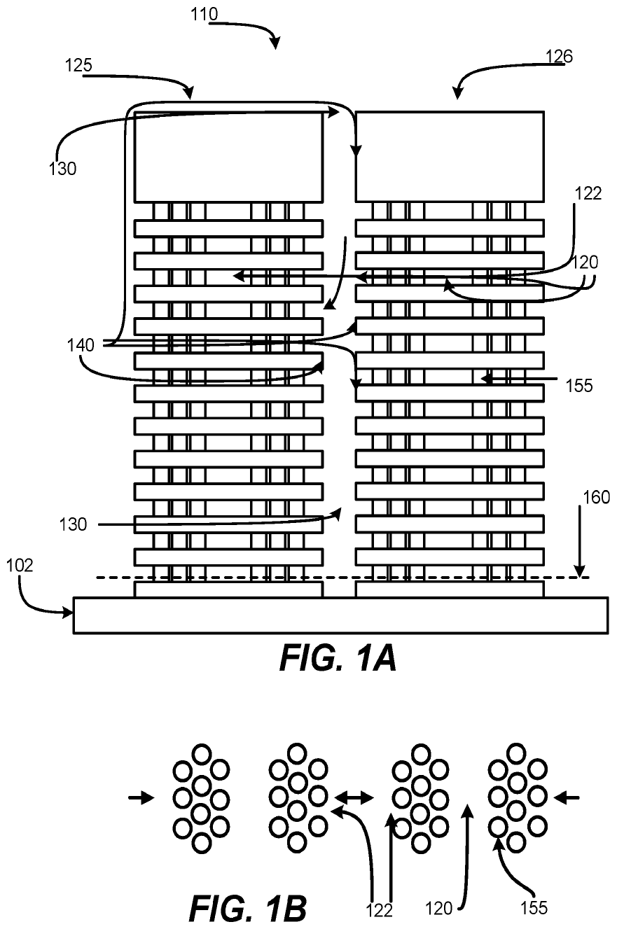

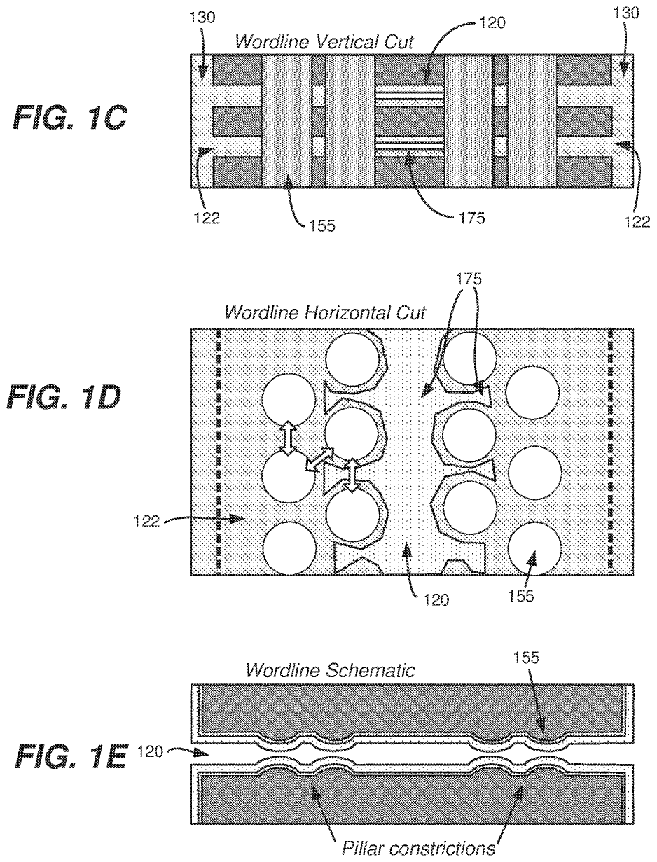

In some embodiments, the methods are used for wordline fill in 3-D NAND structures. FIG. 1A presents a cross-sectional side-view of a 3-D NAND structure 110 (formed on a silicon substrate 102) having VNAND stacks (left 125 and right 126), central vertical structure 130, and a plurality of stacked horizontal features 120 with openings 122 on opposite sidewalls 140 of central vertical structure 130. Note that FIG. 1A displays two stacks of the exhibited 3-D NAND structure 110, which together form the trench-like central vertical structure 130. There may be more than two such stacks arranged in sequence and running spatially parallel to one another with the gap between each adjacent pair of stacks forming a central vertical structure 130, like that illustrated in FIG. 1A. The horizontal features 120 are 3-D memory wordline features that are fluidically accessible from the central vertical structure 130 through the openings 122. The horizontal features 120 present in both the 3-D NAND stacks 125 and 126 shown in FIG. 1A (i.e., the left 3-D NAND stack 125 and the right 3-D NAND stack 126) are also accessible from the other sides of the stacks (far left and far right, respectively) through similar vertical structures formed by additional 3-D NAND stacks (to the far left and far right, but not shown). In other words, each 3-D NAND stack 125, 126 contains a stack of wordline features that are fluidically accessible from both sides of the 3-D NAND stack through a central vertical structure 130. In the particular example schematically illustrated in FIG. 1A, each 3-D NAND stack contains 6 pairs of stacked wordlines, however, in other embodiments, a 3-D NAND memory layout may contain any number of vertically stacked pairs of wordlines.

The wordline features in a 3-D NAND stack may be formed by depositing an alternating stack of silicon oxide and silicon nitride layers, and then selectively removing the nitride layers leaving a stack of oxides layers having gaps between them. These gaps are the wordline features. Any number of wordlines may be vertically stacked in such a 3-D NAND structure so long as there is a technique for forming them available, as well as a technique available to successfully accomplish (substantially) void-free fills of the vertical features. Thus, for example, a 3-D NAND stack may include between 2 and 256 horizontal wordline features, or between 8 and 128 horizontal wordline features, or between 16 and 64 horizontal wordline features, and so forth (the listed ranges understood to include the recited end points).

FIG. 1B presents a cross-sectional top-down view of the same 3-D NAND structure 110 shown in side-view in FIG. 1A with the cross-section taken through the horizontal section 160 as indicated by the dashed horizontal line in FIG. 1A. The cross-section of FIG. 1B illustrates several rows of pillars 155, which run vertically from the base of semiconductor substrate 102 to the top of 3-D NAND stack 110. In some embodiments, these pillars 155 are formed from a polysilicon material. Polysilicon pillars may serve as gate electrodes for stacked memory cells formed within the pillars. The top-view of FIG. 1B illustrates that the pillars 155 form constrictions in the openings 122 to wordline features 120—i.e. fluidic accessibility of wordline features 120 from the central vertical structure 130 via openings 122 (as indicated by the arrows in FIG. 1G) is inhibited by pillars 155. This reduction in fluidic accessibility increases the difficulty of uniformly filling wordline features 120 with material. The structure of wordline features 120 and the challenge of uniformly filling them with tungsten material due to the presence of pillars 155 is further illustrated in FIGS. 1C, 1D, and 1E.

FIG. 1C exhibits a vertical cut through a 3-D NAND structure similar to that shown in FIG. 1A, but here focused on a single pair of wordline features 120. FIG. 1C also schematically illustrates a void 175 in the filled wordline features 120. FIG. 1D also schematically illustrates void 175, but in this figure illustrated via a horizontal cut through pillars 155, similar to the horizontal cut exhibited in FIG. 1G. FIG. 1E illustrates the accumulation of tungsten material around the constriction-forming pillars 155, the accumulation resulting in the pinch-off of openings 122, so that no additional tungsten material can be deposited in the region of voids 175. Apparent from FIGS. 1C and 1D is that void-free tungsten fill relies on migration of sufficient quantities of deposition precursor down through vertical structure 130, through openings 122, past the constricting pillars 155, and into the furthest reaches of wordline features 120, prior to the accumulated deposition of tungsten around pillars 155 causing a pinch-off of the openings 122 and preventing further precursor migration into wordline features 120. Similarly, FIG. 1E exhibits a single wordline feature 120 viewed cross-sectionally from above and illustrates how a generally conformal deposition of tungsten material begins to pinch-off the interior of wordline feature 120 because the significant width of pillars 155 acts to partially block, and/or narrow, and/or constrict what would otherwise be an open path through wordline feature 120. (It should be noted that the example in FIG. 1E can be understood as a 2-D rendering of the 3-D features of the structure of the pillar constrictions shown in FIG. 1D, thus illustrating constrictions that would be seen in a plan view rather than in a cross-sectional view.) Filling three-dimensional structures may use longer and/or more concentrated exposure to precursors to allow the innermost and bottommost areas to be filled.

Examples of feature fill for horizontally-oriented and vertically-oriented features are described below. It should be noted that in at least most cases, the examples are applicable to both horizontally-oriented and vertically-oriented features. Moreover, it should also be noted that in the description below, the term “vertical” may be used to refer to a direction generally orthogonal to the plane of the substrate and the term “lateral” to refer to a direction generally parallel to the plane of the substrate.

Provided herein are methods and apparatuses for filling structures with W using treatment in combination with a booster gas that further enhances inhibition effects.

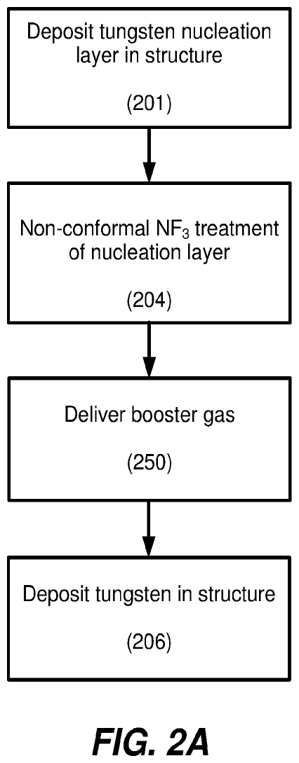

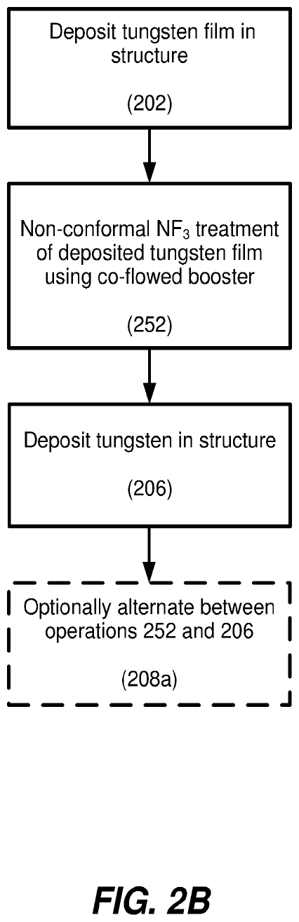

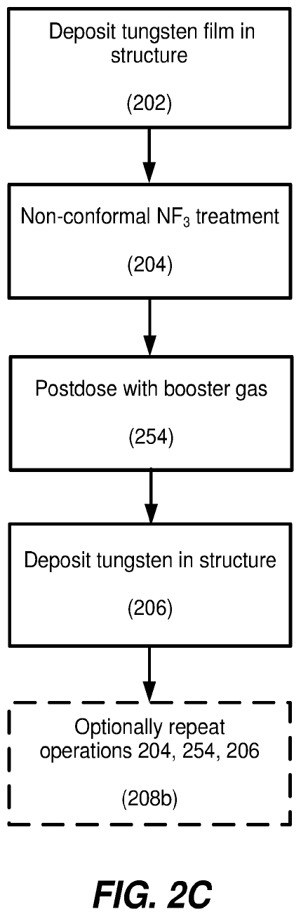

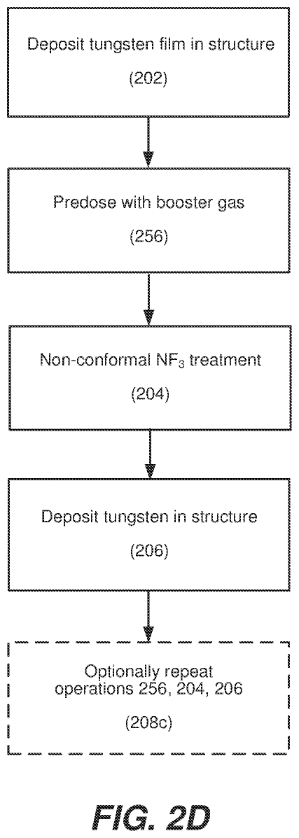

FIG. 2A is a process diagram illustrating operations in filling a structure with tungsten involving a non-conformal NF₃ treatment in accordance with certain disclosed embodiments.

First, a W nucleation layer is deposited in an operation 201. In many embodiments, operation 202 is a generally conformal deposition that lines the exposed surfaces of the structures. For example, in a 3D NAND structure such as that shown in FIG. 1A, the W film lines the wordline features 120. According to various embodiments, the W film is deposited using an atomic layer deposition (ALD) process to achieve good conformality. A further description of W ALD processes is given below.

Next, in an operation 204, the deposited W nucleation layer is non-conformally treated by nitrogen trifluoride (NF₃). Non-conformal treatment in this context refers to the treatment being preferentially applied at and near the opening or openings of the feature than in the feature interior. For 3-D NAND structures, the treatment may be conformal in the vertical direction such that the bottom wordline feature is treated to approximately the same extent as the top wordline feature, while non-conformal in that the interior of the wordline features are not exposed to the treatment or to a significantly lesser extent than the feature openings.

In some embodiments, the NF₃ treatment both inhibits subsequent tungsten nucleation and etches deposited tungsten. Nucleation inhibition inhibits subsequent tungsten nucleation at the treated surfaces. It can involve one or more of: deposition of an inhibition film, reaction of treatment species with the W film to form a compound film, and adsorption of inhibition species. During the subsequent deposition operation, there is a nucleation delay on the inhibited portions of the underlying film relative to the non-or lesser-inhibited portions. Etch removes deposited film at the treated surfaces. This can involve reacting an etchant species with the tungsten film to form a gaseous byproduct that is then removed.

Other gases such as ammonia (NH₃) may be used for thermal inhibition processes. However, using NF₃ offers advantages over other treatments. One advantage is that NF₃ both inhibits tungsten nucleation and etches deposited tungsten from the treated surfaces. Nitrogen acts as an inhibition species and fluorine act as an etchant. To perform a purely inhibition treatment, operation 204 can involve exposing the W film to a nitrogen-containing chemistry that does not contain fluorine or other halogens. To perform a purely etch treatment, operation 204 can involve exposing the W film to a halogen-containing chemistry that does not contain nitrogen. Treating the W film with NF₃, a nitrogen-containing and halogen-containing chemistry, inhibits W nucleation and etches the W film. Moreover, as discussed further below, NF₃ allows the inhibition and deposition operations to be performed in the same station with a single plenum showerhead.

In some embodiments, a treatment gas is pressurized to level significantly higher than the chamber pressure prior to introduction to chamber. This facilitates the gas reaching the bottommost portion of the vertical structure. In the example of NF₃ gas, the NF₃ gas may be pressurized in a charge volume to a pressure between 10 Torr and 1000 Torr. In some embodiments, the pressure is between 400 Torr and 500 Torr. Charge volumes are discussed further below.

As discussed further below, operation 204 may be a continuous flow or pulsed process. In the latter case, different gases may be pulsed in sequence to tune the treatment.

Next, in an operation 250, a booster gas is delivered. The booster gas is used to increase the inhibition effect of the treatment performed in operation 205. In some embodiments, the booster gas is delivered at the same time as the non-conformal NF₃ treatment in operation 204. Such examples are further described below with respect to FIG. 2B. In some embodiments, the booster gas is delivered after non-conformal NF₃ treatment in operation 204. Such examples are further described below with respect to FIG. 2C. In some embodiments, the booster gas is delivered before non-conformal NF₃ treatment in operation 204. Such examples are further described below with respect to FIG. 2D.

The booster gas is hydrogen (H₂) gas in various embodiments. The booster gas may be a mixed with one or more of argon (Ar) gas and nitrogen (N₂) gas. For example, the booster gas may be a mixture of H₂ and Ar (H₂/Ar) or may be a mixture of H₂, N₂, and Ar (H₂/N₂/Ar). Either or both of the Ar and N₂ gas may be used as a dilution gas or may be used as a delivery gas to assist in delivering H₂ to the station processing the substrate having the W film.

In various embodiments, the booster gas has a higher concentration than the NF₃ gas used in treatment so as to tailor the amount of NF₃ during inhibition. The relative amount of booster gas relative to NF₃ gas can affect how much inhibition effect is increased or decreased. Example ratios that would increase inhibition effects include 1:5 to about 1:10 of NF₃ to H₂ gas.

In an operation 206, W is deposited in the structure. In some embodiments, this may be the same as Dep1 described further below, or may be Dep2 as described further below.

FIG. 2B is a process diagram illustrating operations in filling a structure with tungsten involving a non-conformal NF₃ treatment in accordance with certain disclosed embodiments.

First, a W film is deposited in the structure in an operation 202, which may be the same as operation 202 with respect to FIG. 2A above. In some embodiments, the W film is W deposited after depositing the W nucleation layer (such as after operation 201 of FIG. 2A). This operation may be referred to as Dep1. In many embodiments, like operation 201, operation 202 is a generally conformal deposition that lines the exposed surfaces of the structures. For example, in a 3-D NAND structure such as that shown in FIG. 1A, the W film lines the wordline features 120. According to various embodiments, the W film is deposited using ALD to achieve good conformality. After operation 202, the features are not closed off with W, but sufficiently open to allow further reactant gases to enter the features in a subsequent deposition.

Next, in an operation 252, the deposited W film is non-conformally treated by NF₃ with a co-flowed booster gas. The booster gas is co-flowed in that it is flowed to the station housing the substrate having the structure with the W film at the same time that NF₃ is flowed to the station. The booster gas may be any of those described above with respect to FIG. 2A. The ratio of concentration of NF₃ gas to booster gas may be any of those described above with respect to FIG. 2A.

After operation 252, a second deposition is performed in operation 206. The second deposition may be performed by an ALD or CVD process. For deposition into 3-D NAND structures, an ALD process may be used to allow for good step coverage throughout the structure. Gases more easily reach feature interiors due to the effects of the treatment. After an etch process, film deposited near the feature entrance is removed, allowing more space for gases to reach the interior of the feature and preventing pinch-off. In some embodiments, enough W film may be removed such that an underlying surface is wholly or partially exposed, increasing nucleation delay at these areas. Using the booster gas increases nucleation delay even more than using the NF₃ alone. After an inhibition process, nucleation delay is increased, allowing an inside-out fill process. Operation 206, which may be referred to as a Dep2 process, may complete fill of the structures in some embodiments. In other embodiments, one more additional treatment/deposition operations may be performed.

To tailor lateral non-conformality in the wordlines, pressure and treatment gas flow rate may be adjusted. Lower chamber pressure and lower treatment gas flow rate (and/or concentration) promotes treatment at the openings of the wordline features over treatment within the interiors of the wordline features. That is, lower chamber pressure may help promote non-conformal inhibition treatment. Thus, in some embodiments, chamber pressure may lower from operation 202 to 252 to 206 or any combination thereof. Example chamber pressures range from 3 Torr to 40 Torr.

According to various embodiments, operations 202, 252, and 206 may be performed in the same processing chamber or in different processing chambers. If performed in the same chamber, they may be performed in a single-station or multi-station chamber. In a multi-station chamber, various operations may be performed at various stations. For example, operation 202 may be performed in a first station and operation 252 in a second station. In another example, operation 202 and operation 206 may be performed in a first station and operation 252 in a second station. In some embodiments, while various operations are performed in separate stations within a single chamber, only a single operation, i.e., operation 202, depositing W film in a structure, may be performed at a time. In another embodiment, when multiple substrates are being processed, various operations may occur concurrently. For example, a first substrate is at station one for operation 202 and a second substrate is at station two for operation 252 in the same multi-station chamber. Both operation 202 and operation 252 may proceed concurrently in the same multi-station chamber. In some embodiments, chamber pressure may be low to prevent any cross-contamination or safety issues. In one example, in operation 202, a nucleation layer may be deposited using a boron-containing reducing agent (e.g., B₂H₆) in station one on a first substrate. A second substrate may be undergoing operation 252 in a second station. Both the nucleation layer deposition of B₂H₆ in station one and the deposition of NF₃ in station two can occur concurrently in the same multi-station chamber. To achieve this, the chamber pressure is set to a lower pressure, such as a pressure below 25 Torr.

In an operation 208a, operations 252 and 206 may be optionally alternated, such as in temporally alternating pulses or in cycles. For example, one cycle that may be repeated may involve (1) treatment using NF₃ and H₂ (or H₂/Ar, or H₂/N₂/Ar), and (2) deposition of W.

FIG. 2C is a process diagram illustrating operations in filling a structure with tungsten using certain disclosed embodiments. FIG. 2C also includes depositing W in the structure in an operation 202, which maybe the same as operation 202 in FIGS. 2A and 2B. Next, non-conformal NF₃ treatment is performed in an operation 204. Unlike FIG. 2B, here treatment is performed without a booster gas. Next, in an operation 254, a booster gas is used post-dose (“dose” referring to the dose of NF₃ treatment). The booster gas may be the same as used in operation 252 in FIG. 2B or operation 250 in FIG. 2A. Next, in an operation 206, W is deposited in the structure, which may be the same as operation 206 in FIG. 2B. In operation 208b, operations 204, 254, and 206 are optionally repeated in cycles.

FIG. 2D is a process diagram illustrating operations in filling a structure with tungsten using certain disclosed embodiments. FIG. 2D also includes depositing W in the structure in an operation 202, which maybe the same as operation 202 in FIGS. 2A, 2B, and 2C. Next, in an operation 256, a booster gas is used pre-dose (“dose” referring to the dose of NF₃ treatment). The booster gas may be the same as used in operation 252 in FIG. 2B or operation 250 in FIG. 2A. Next, a non-conformal NF₃ treatment is performed in an operation 204. The treatment is performed without a booster gas; that is, prior to treatment, the booster gas delivery is diverted or stopped, and the NF₃ is delivered to perform treatment without simultaneously delivering the booster gas. Next, in an operation 206, W is deposited in the structure, which may be the same as operation 206 in FIG. 2B. In operation 208c, operations 256, 204, and 206 are optionally repeated in cycles.

While certain disclosed embodiments are described above with respect to FIG. 2A-2D, it will be understood that the booster gas may be delivered before, during, or after NF₃ treatment to booster the inhibition effect, and inhibition may be generally performed after depositing the initial W nucleation layer, or after depositing some W bulk material, or after deposited most of the W bulk, or any combination thereof. It will also be understood that in some embodiments, inhibition is not performed when the structures are almost filled or can be completely filled with bulk W without forming voids or gaps.

FIG. 3-5 illustrate examples of inhibition and etching effects, respectively, of a treatment of a 3-D NAND structure with tungsten in sequence. FIG. 3-5 depicts inhibition effects of a nitrogen treatment. As discussed above, the NF₃ treatment inhibits tungsten nucleation as depicted in FIG. 3-5. The inhibition effects of the NF₃ treatment may both occur as a result of operations 204, 250, 252, 254, and 256, but for clarity, are shown separately in different figures.

FIG. 3 illustrates an example of a process performed to fill a 3-D NAND structure with tungsten that includes an inhibition operation. In FIG. 3, a cross-sectional view of a single wordline of a 3-D NAND structure is shown. (As in the example of FIG. 1E, wordline features in FIG. 3 show pillar constrictions that would be seen in a plan view rather than a cross-sectional view to illustrate the constrictions.) In FIG. 3, the wordline feature is shown after a Dep1 process. An under-layer 306 is shown; this may be for example a titanium nitride (TiN), tungsten nitride (WN), or tungsten carbonitride (WCN) barrier layer. A conformal W film 305 lines the feature surfaces including the surfaces of the under-layer 306. In some embodiments, the conformal W film 305 is deposited directly on a dielectric surface such as an aluminum oxide or silicon oxide surface. The W layer 305 may be a nucleation layer, a nucleation and a bulk layer, or a bulk layer.

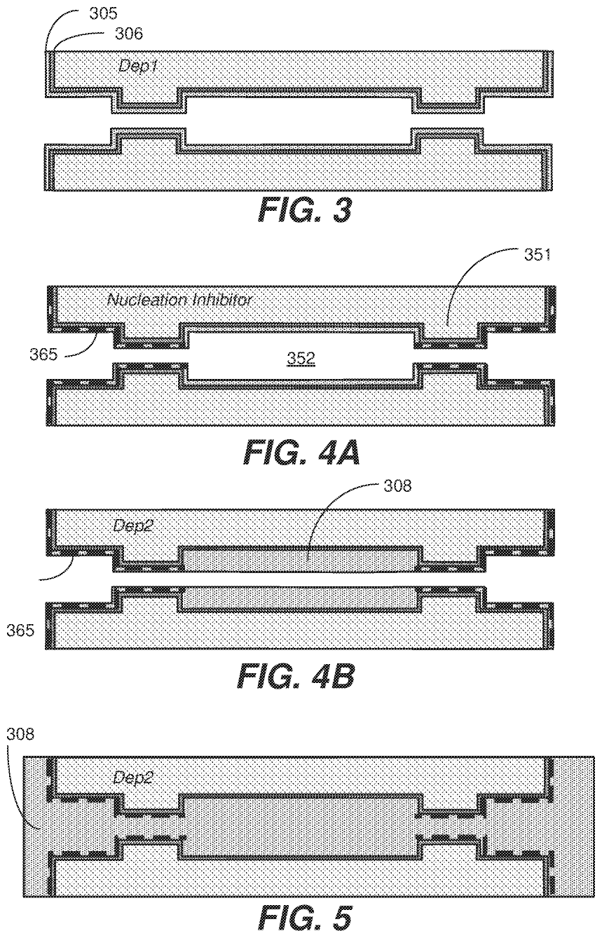

Next, in FIG. 4A, the feature is exposed to an inhibition chemistry with a booster gas to inhibit portions 365. In this example, the portions 365 through pillar constrictions 351 are inhibited while the surfaces of the interior at 352 are not inhibited. Thus, in the example of FIG. 3, the inhibition treatment is laterally non-conformal. However, the treatment may be uniform in a vertical direction such that each wordline is inhibited at approximately the same areas.

Next, in FIG. 4B, a process is performed to selectively deposit W accordance with the inhibition profile: bulk W 308 is preferentially deposited on the non-inhibited portions of the W layer 305, such that hard-to-fill regions behind constrictions are filled.

In this example, the bulk deposition continues, filling the remainder of the feature with bulk W 308 as shown in FIG. 5.

### GAS FLOW CONFIGURATION

In some embodiments, charge volumes may be used to deliver gas to achieve lateral non-conformality but have top-to-bottom uniformity. Using charge volumes can enable delivering treatment gases to the bottom of high aspect ratio structures, such as to the bottom wordline of 3-D NAND structures. The pressurized gas flows from the charge volume through a showerhead and reaches the substrate.

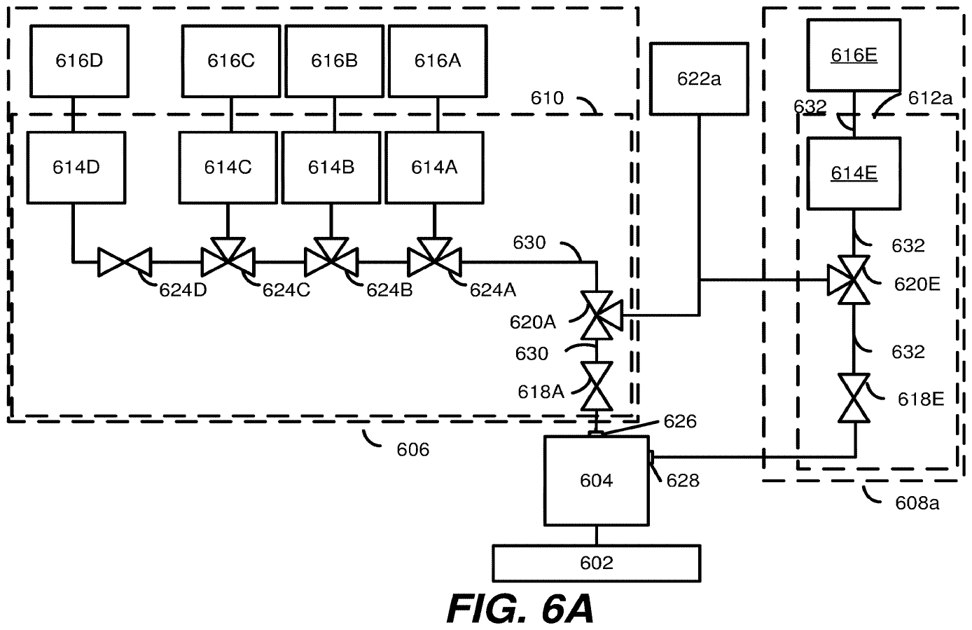

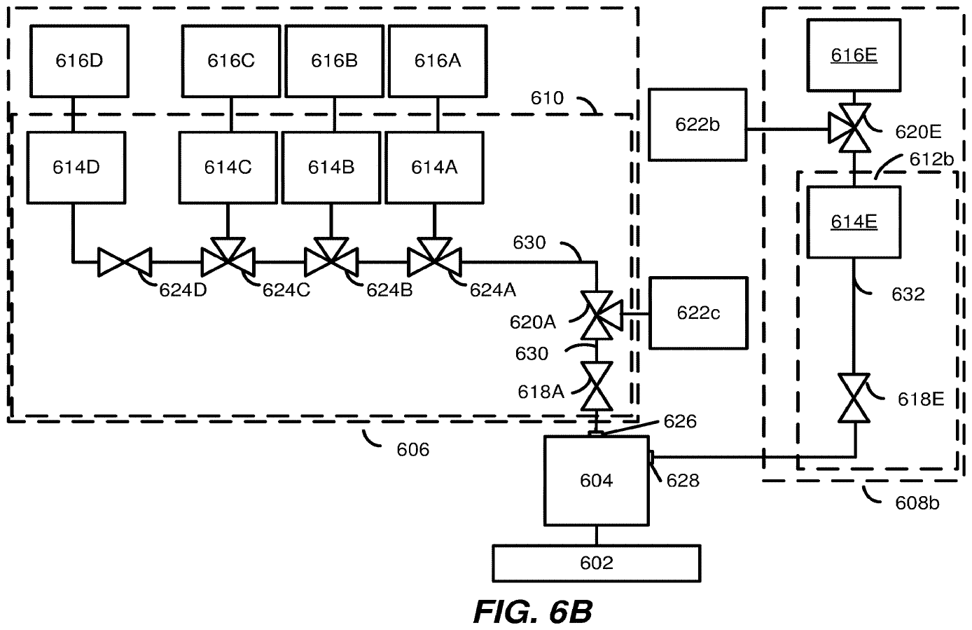

An example apparatus is shown schematically in FIG. 6A, in which the gas sources are connected to charge volumes. In some embodiments, one or more gas sources may be connected to multiple charge volumes. The apparatus includes a gas manifold system, which provides line charges to the various gas distribution lines. The manifolds provide the treatment gases and purge gas to the deposition chamber through valved charged volumes. The various valves are opened or closed to provide a line charge, i.e., to pressurize the distribution lines.

FIG. 6A depicts a schematic showing how process gases may be provided to a wafer processing chamber (not shown) via a showerhead 602. Shown in the schematic are two gas zones fluidically connected to the showerhead 602 through a dual inlet chamber 604. In the example described below, the first gas zone 606 includes deposition and purge gases. The second gas zone 608a includes a pressure gas and an inhibition gas that is chemically incompatible with the deposition gases. In other embodiments, the gas zones may be used to separately supply chemically incompatible gases to the showerhead 602.

In the described example, the deposition gases include a metal precursor gas such as tungsten hexafluoride (WF₆) and hydrogen (H₂). Examples of metal precursor gases are provided below. The purge gas may be argon (Ar) or other chemically inert gas. The inhibition gas may be nitrogen trifluoride (NF₃), which can be used to inhibit nucleation on the deposited metal. H₂ and NF₃ are chemically incompatible as they can react explosively. Other examples of inhibition gases as well as other gases that may be supplied in the second gas zone are provided below. Another gas that may be delivered is a booster gas. The booster gas may be H₂, or a mixture of H₂/Ar, or a mixture of H₂/N₂/Ar.

The showerhead 602 distributes gases to the chamber (not shown). Fluidically interposed between the showerhead 602 and the two gas zones is a dual inlet chamber 604. The dual inlet chamber 604 is fluidically connected to the first gas zone 606 and the second gas zone 608a. The dual inlet chamber 604 has a first inlet 626 and a second inlet 628. Each gas zone connects to one of the two inlets of the dual inlet chamber 604. In the example shown in FIG. 6A, the first gas zone 606 connects to the first inlet 626 and the second gas zone 608a connects to the second inlet 628 of the dual inlet chamber 604.

In some embodiments, the dual inlet chamber 604 may be used to flow gases separately from each gas zone to the showerhead. The individual gases from each gas zone may mix in the dual inlet chamber 604. The dual inlet chamber 604 may be used to mix gases from the first gas zone 606 and the second gas zone 608a prior to the gas mixture flowing to the chamber via the showerhead 602. However, this may be avoided in situations in which the gas flows include chemically incompatible gases.

In some embodiments, the dual inlet chamber 604 includes an annulus. Further details of the dual inlet chamber 604 are provided below.

In the example of FIG. 6A, the second gas zone 608 includes an inhibition gas source 616E and an inhibition gas manifold 612a. The inhibition gas manifold 612a is fluidically interposed between the inhibition gas source 616E and the dual inlet chamber 604. The inhibition gas source 616E supplies the inhibition gas to the inhibition gas manifold 612a.

The inhibition gas manifold 612a includes an injection valve 618E, a divert gas valve 620E, and a charge volume 614E. The three components, the injection valve 618E, the divert gas valve 620E, and the charge volume 614E, are fluidically connected to each other via a main inhibition gas line 632 with the divert gas valve being fluidically interposed between the injection valve and the charge volume. The injection valve 618E is fluidically connected to the dual inlet chamber 604 and fluidically interposed between the dual inlet chamber and the divert gas valve 620E. The injection valve 618E may be used to control the flow of inhibition gas from the inhibition gas manifold 612a into the dual inlet chamber 604. The divert gas valve 620E is fluidically connected to a divert manifold 622a and directs the flow of inhibition gas from the charge volume 614E to the injection valve 618E or to the divert manifold 622a. The divert manifold 622a may be used to relieve pressure from the inhibition gas manifold 612a, to clear the inhibition gas manifold 612a of gas, or to stabilize the flow of inhibition gases. When inhibition gas is being flowed into the showerhead, the divert manifold 622a may be used to relieve pressurize gas, ensuring the gas flows from the inhibition gas manifold 612a is stabilized before reaching the showerhead 602. The divert manifold 622a can be used to discharge any gas remaining in the inhibition gas manifold 612, including inhibition gas still in the charge volume 614E. In some cases, it may desirable to clear the inhibition gas manifold 612a of all gases prior to the flow of additional inhibition gas into the inhibition gas manifold. The charge volume 614E is fluidically interposed between the inhibition gas source 616E and the divert gas valve 620E. The charge volume 614E stores and pressurizes the inhibition gas from the inhibition gas source 616E. When either the divert gas valve 620E is closed or when the divert gas valve directs the flow of gas to the injection valve 618E and the injection valve is closed, gas may be flowed from the inhibition gas source 616E to the charge volume 614E where the gas is stored and pressurized.

In one example, the second gas zone 608 includes NF₃. When the NF₃ gas is not being used in the process, the injection valve 618E is closed to prevent NF₃ gas from being flowed into the dual inlet chamber 604. The inhibition gas source 616E flows NF₃ gas into main inhibition gas line 632 and into the charge volume 614E. Since the injection valve 618 is closed, the NF₃ gas will fill the charge volume 614E and will become pressurized. The pressurized NF₃ gas increases the mass flow rate of the gas when the gas is released by opening the injection valve 618. When the process uses the flow of NF₃ to the substrate, the injection valve 618E is opened. The pressurized NF₃ gas flows into the dual inlet chamber 604 and into the showerhead 602.

While the inhibition gas pressure is building in the charge volume 614E, the showerhead 602 may flow process gas from the first gas zone 606 into the chamber. The first gas zone 606 has a process gas manifold 610 and at least one gas source 616. In the embodiment shown, there are four different gas sources 616. In some embodiments, there may be a single gas source 616. In other embodiments, there may be multiple gas sources. As indicated above, examples of gases supplied from the gas sources are Ar, H₂, N₂, and WF₆. In the embodiment shown, there are four individual gas sources 616. Each process gas source 616A, 616B, 616C, and 616D supplies a gas to a separate line within the process gas manifold 610. In some embodiments, the gas type for each gas source 616 may be unique for each line, e.g., the gas in 616A is different than the gas in 616B, the gas in 616A and 616B are different than the gas in 616C, etc. In other embodiments, the same gas may be used as the gas for two or more gas sources, e.g., the gas in process gas source 616A may be the same gas as in the gas source 616B.

The first gas zone 606 has the process gas manifold 610. In the embodiment shown, the process gas manifold 610 has an injection valve 618A, a divert gas valve 620A, and charge volumes 614 with corresponding charge volume valves 624. The injection valve 618A fluidically connects the gas from the process gas manifold 610 to the dual inlet chamber 604. The divert gas valve 620A is fluidically interposed between the injection valve 618A and the charge volume valves 624. The injection valve 618A, the divert gas valves 620A, and charge volume valves 624 are fluidically connected via a main process gas line 630. Similar to the divert gas valve 620E in the inhibition gas manifold 612, the divert gas valve 620A in the process gas manifold 610 can divert gas within the main process gas line 630 and/or from the charge volumes 614 to the divert manifold 622a.

Process gas from the process gas sources 616A, 616B, 616C, 616D are flowed into the corresponding charge volumes 614A, 614B, 614C, 614D. When a charge volume valve 624 is closed, the process gas from a corresponding gas source 616 may fill the corresponding charge volume 614. As the process gas from the process gas sources 616 fills the charge volume 614, the gas may become pressurized. The charge volumes 614 store the pressurize gas until the gas is released into the main process gas line 630 by opening the corresponding charge volume valve 624.

In one example, WF₆ gas is provided by the process gas source 616A. When WF₆ is not used for wafer processing, the charge volume valve 624A is closed. The process gas source 616A flows WF₆ into the charge volume 614A. The WF₆ gas fills the charge volume 614A and becomes pressurized. When the WF₆ gas is pressurized to a desired pressure in the charge volume 614A, the process gas source 616A ceases flow of WF₆ gas into the charge volume. Once wafer processing in the chamber uses WF₆ gas, the charge volume valves 624B, 624C, and 624D for the other gases close, preventing the gas in the other charge volumes 614 from flowing into the main process gas line 630. Similarly, the injection valve 618E from the inhibition gas manifold 612a is closed to prevent inhibition gas from entering the dual inlet chamber 604. The charge volume valve 624A for the WF₆ gas is opened and the WF₆ gas stored within the charge volume 614 flows into the main process gas line 630. The WF₆ gas flows through the divert gas valve 620A and through the injection valve 618A into the dual inlet chamber 604. From the dual inlet chamber 604, the gas flows into the showerhead 602 before being injected into the chamber for wafer processing.

In the process described in FIG. 2A-2D, the deposition of W film in the structure may use H₂ as a reducing agent and the non-conformal treatment 204 may use NF₃ to inhibit and etch. However, when H₂ and NF₃ gases mix together, they may react explosively. Thus, preventing inadvertent mixtures of the two gases is critical. In this example, the gas source 616B in the first gas zone 606 provides H₂ gas to the process gas manifold 610 and the gas source 616E in the second gas zone 608 provides NF₃ gas to the inhibition gas manifold 612a. Because H₂ can be used as a reducing agent and as an inhibition booster, the same gas source may be used to deliver H₂ depending on the timing of delivery of other gases in the tool (for example, H₂ may be flowed both when treating with NF₃ and when depositing W). As described above, for the non-conformal treatment of the deposited tungsten film, NF₃ gas is flowed into the chamber. After a purge, deposition gases such as WF₆ and H₂ gas is flowed into the chamber. H₂ is flowed to the showerhead through inlet 626 to mix with NF₃ inside dual inlet chamber 604. NF₃ gas is flowed through the inhibition gas manifold 612a through the dual inlet chamber 604 through the showerhead 602 to the chamber (not shown). In some embodiments where NF₃ is flowed separately from H₂, prior to NF₃ gas being flowed into the chamber, the charge volume valve 624B for the H₂ gas is closed and an inert gas is flowed throughout the lines to clear any remaining H₂ gas from the line. Subsequently, NF₃ gas is flowed through the inhibition gas manifold 612a through the dual inlet chamber 604 into the showerhead 602. Inert gas may be supplied by a gas source, such as the gas source 616C, in the first gas zone 606, or may be supplied by another gas source (not shown) fluidically connected to the first inlet 626 of the dual inlet chamber 604. Concurrent to the NF₃ gas being flowed, the inert gas in the first gas zone 606 flows through the process gas manifold 610 into the dual inlet chamber 604 via the first inlet 626. This prevents the NF₃ gas in the dual inlet chamber 604 from flowing out through the first inlet 626 and forces the NF₃ gas into the showerhead 602. The inert gas flowing from the process gas manifold 610 prevents NF₃ gas from flowing into the process gas manifold 610 and creates a barrier between the NF₃ gas and the H₂ gas. Alternatively, when the inert gas from an outside source (not shown) is used, the injection valve 618 is closed, preventing any gas from flowing into or out of the process gas manifold 610. The outside gas source flows the inert gas into the first inlet 626 of the dual inlet chamber 604, thus preventing any NF₃ gas from the second gas zone 608 from flowing out of the first inlet 626 and into the first gas zone 606 where the H₂ gas is. Thus, in both cases, the NF₃ gas and the H₂ gas have at least two barriers between them, the closed valve and the inert gas, preventing any potential mixture between the two gases.

After the NF₃ gas is flowed, a purge is performed. The purge may clear any remaining NF₃ gas in the showerhead 602, the dual inlet chamber 604, and the lines. Once the flow path for the H₂ gas is purged and cleared of NF₃ gas, H₂ gas can be flowed into the process chamber. An inert gas coming from the second gas zone 608 is flowed to the dual inlet chamber 604 and used to prevent H₂ gas from flowing back up stream towards the NF₃ gas. In addition, the injection valve 618E may be closed to prevent NF₃ gas from flowing into the dual inlet chamber 604 and mixing with the H₂ gas. In some embodiments, where NF₃ and H₂ are delivered simultaneously, both 618A and 618E are open. Additionally, both gases may be diluted with Ar from each gas zone.

In multi-station chambers, each station has a corresponding showerhead 602. Depending on the tool configuration, each station may also have a corresponding process gas manifold 610 and inhibition gas manifold 612a. In some embodiments, some stations in the multi-station chamber have only a process gas manifold 610 while other stations have both the process gas manifold 610 and the inhibition gas manifold 612a. In this embodiment, the stations with both the process gas manifold 610 and the inhibition gas manifold 612a will have a corresponding dual inlet chamber 604. For example, a multi-station chamber with four stations have station one and station four supplied with corresponding process gas manifolds. Stations three and station four have both corresponding process gas manifolds 610 and corresponding inhibition gas manifolds 612a. In this example, station three and station four will each have a corresponding dual inlet chamber 604 fluidically interposed between the corresponding showerhead 602 and corresponding process gas manifolds 610 and corresponding inhibition gas manifolds 612a. Depending on the tool configuration, each of the process gas manifolds 610 may be supplied with the same gases or may be supplied with different gases. Similarly, depending on the tool configuration, each of the inhibition gas manifolds 612a may be supplied with the same inhibition gas or different inhibition gas.

FIG. 6B shows depicts another schematic showing how process gases may be provided to a wafer processing chamber (not shown) via a showerhead 602. In the example of FIG. 6B, the second gas zone 608 includes an inhibition gas source 616E and an inhibition gas manifold 612a. The inhibition gas manifold 612b is fluidically interposed between the inhibition gas source 616E and the dual inlet chamber 604. The inhibition gas source 616E supplies the inhibition gas to the inhibition gas manifold 612b.

The first gas zone 606 and its components and gas flow structure may be the same as first gas zone 606 described above with respect to FIG. 6A. The showerhead 602 and dual inlet chamber 604 may be the same as those described above with respect to FIG. 6A.

The second gas zone 608b includes a pressure gas and an inhibition gas that is chemically incompatible with the deposition gases. In other embodiments, the gas zones may be used to separately supply chemically incompatible gases to the showerhead 602. The system shown in FIG. 6B allows for independently controlled stations, utilization of one inhibition gas manifold, and implementation of various disclosed embodiments whereby each station can either be for nucleation, Dep1, Dep2, inhibition, and/or booster gas exposure.

The showerhead 602 distributes gases to the chamber (not shown). Fluidically interposed between the showerhead 602 and the two gas zones is a dual inlet chamber 604. The dual inlet chamber 604 is fluidically connected to the first gas zone 606 and the second gas zone 608b. Like FIG. 6A, the dual inlet chamber 604 has a first inlet 626 and a second inlet 628. Each gas zone connects to one of the two inlets of the dual inlet chamber 604. In the example shown in FIG. 6B, the first gas zone 606 connects to the first inlet 626 and the second gas zone 608b connects to the second inlet 628 of the dual inlet chamber 604.

In the example of FIG. 6B, the second gas zone 608b includes an inhibition gas source 616E and an inhibition gas manifold 612b. The inhibition gas manifold 612b is fluidically interposed between the inhibition gas source 616E and the dual inlet chamber 604. The inhibition gas source 616E supplies the inhibition gas to the inhibition gas manifold 612b. The inhibition gas source 616E uses a divert gas valve 620E. Unlike FIG. 6A, divert gas valve 620E is not part of inhibition gas manifold 612b. The divert gas valve is fluidically interposed between the inhibition gas source 616E and the inhibition gas manifold 612b.

The inhibition gas manifold 612b includes an injection valve 618E, and a charge volume 614E. The two components, the injection valve 618E, and the charge volume 614E, are fluidically connected to each other via a main inhibition gas line 632. The injection valve 618E is fluidically connected to the dual inlet chamber 604 and fluidically interposed between the dual inlet chamber and the charge volume 614E. The injection valve 618E may be used to control the flow of inhibition gas from the inhibition gas manifold 612b into the dual inlet chamber 604. The divert gas valve 620E is fluidically connected to a divert manifold 622b and directs the flow of inhibition gas from the inhibition gas source 616E to charge volume 614E. The divert manifold 622b may be used to relieve pressure from the inhibition gas manifold 612, to clear the inhibition gas manifold 612b of gas, or to stabilize the flow of inhibition gases. When inhibition gas is being flowed into the showerhead, the divert manifold 622b may be used to relieve pressurize gas, ensuring the gas flows from the inhibition gas manifold 612b is stabilized before reaching the showerhead 602. The divert manifold 622b can be used to discharge any gas remaining in the inhibition gas manifold 612, including inhibition gas still in the charge volume 614E. In some cases, it may desirable to clear the inhibition gas manifold 612b of all gases prior to the flow of additional inhibition gas into the inhibition gas manifold. The charge volume 614E is fluidically interposed between the inhibition gas source 616E and the divert gas valve 620E. The charge volume 614E stores and pressurizes the inhibition gas from the inhibition gas source 616E.

Top plate divert manifold 622c is used to regulate divert gas valve 620A. As noted above, the divert gas valve 620A is fluidically interposed between the injection valve 618A and the charge volume valves 624. The injection valve 618A, the divert gas valves 620A, and charge volume valves 624 are fluidically connected via a main process gas line 630. Similar to the divert gas valve 620E in the inhibition gas manifold 612, the divert gas valve 620A in the process gas manifold 610 can divert gas within the main process gas line 630 and/or from the charge volumes 614A, 614B, 614C, and 614D to the divert manifold 622c.

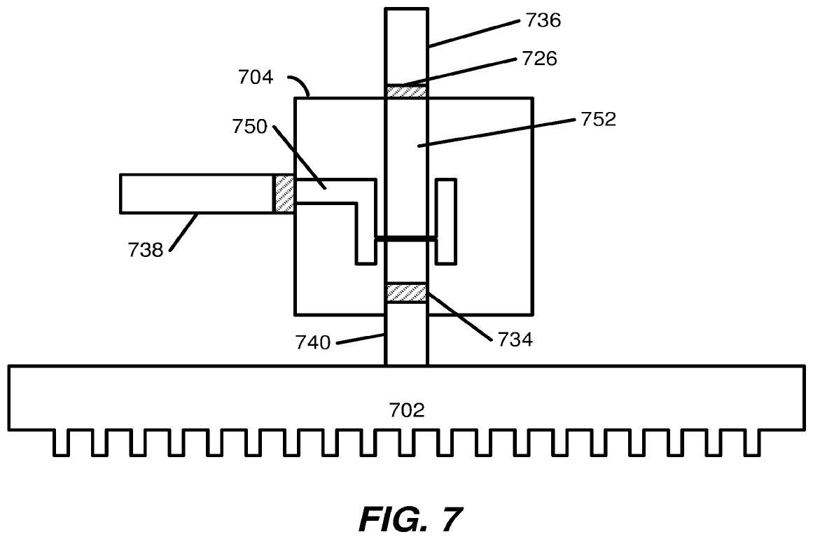

FIG. 7 shows an example of an arrangement of a dual inlet chamber 704 and showerhead 702. The dual inlet chamber 704 has a first inlet 726, a second inlet 728, and an outlet 734. The showerhead 702 and the dual inlet chamber 704 are fluidically connected to each other via an outlet gas line 740. The dual inlet chamber 704 may be placed as close as possible to the showerhead 702. For example, the dual inlet chamber 704 may be placed immediately outside the processing chamber (not shown). By placing the dual inlet chamber 704 close to the showerhead 702, gas in the dual inlet chamber may reach the showerhead 702 quickly to decrease wafer processing time and the pressurized gas remains pressurized, thus allowing gas to flow completely down the 3-D NAND structure.

In the example shown, the first inlet 726 fluidically connects a first inlet gas line 736 to the dual inlet chamber 704 and the second inlet 728 fluidically connects a second inlet gas line 738 to the dual inlet chamber. In some embodiments, the first inlet gas line 736 may be fluidically connected to the first gas zone (not shown) and the second inlet gas line 738 may be fluidically connected to the second gas zone (not shown) as discussed in FIGS. 6A and 6B.

The dual inlet chamber 704 may have a single gas or multiple gases flowed through the dual inlet chamber and out through the outlet 734. In some embodiments, the first inlet 726 may have a gas flowed into the dual inlet chamber 704 and the second inlet 728 has a second gas flowed into the dual inlet chamber. The dual inlet chamber 704 may allow the two gases to mix and form a gas mixture of the two gases. The newly formed gas mixture may be flowed out of the dual inlet chamber 704 through the outlet 734 and into the showerhead 702 for dispersion into the processing chamber (not shown).

FIG. 7 shows a dual inlet chamber 704 including an annulus 750. The dual inlet chamber 704 allows for uniform gas distribution from both the first inlet 726 and the second inlet 728 to the outlet 734. Gas entering from the first inlet 726 travels through main line 752 directly to the outlet 734 and into the showerhead 702. Gas entering from the side of the dual inlet chamber 704, through the second inlet 728 enters through a side of the annulus 750. The annulus 750 evenly distributes the delivery of gas from the second inlet 728, the side of the annulus, to the main line 752. Thus, the annulus allows for uniform distribution of gases from both the first inlet 726 and the second inlet 728 to the outlet 734 and into the showerhead 702.

Below the dual inlet chamber 704 is the showerhead 702. The showerhead distributes the gas from the dual inlet chamber 704 into the chamber (not shown). The showerhead may be a single plenum or a dual plenum showerhead. The treatment process using NF₃ and H₂ (or H₂/Ar, or H₂/N₂/Ar) is advantageous over other treatment using other gases, such as ammonia (NH₃), because it allows for a single plenum showerhead. NH₃ gas is difficult to purge and may leave residue (after a purge) in the hardware. The residue may react with other process gases such as WF₆, SiH₄, and B₂H₆. Thus, when a gas like NH₃ is used for the treatment process, a dual plenum showerhead prevents cross contamination of the NH₃ gas residue left in the showerhead and the other process gases. However, NF₃ gas allows a single plenum showerhead to be used. While NF₃ may be reactive with other process gases, a purge operation is able to clear the NF₃ gas and NF₃ residue from the showerhead. Thus, a single plenum may be used as long as the gases are purged from the showerhead 702 before the use of the next gas.

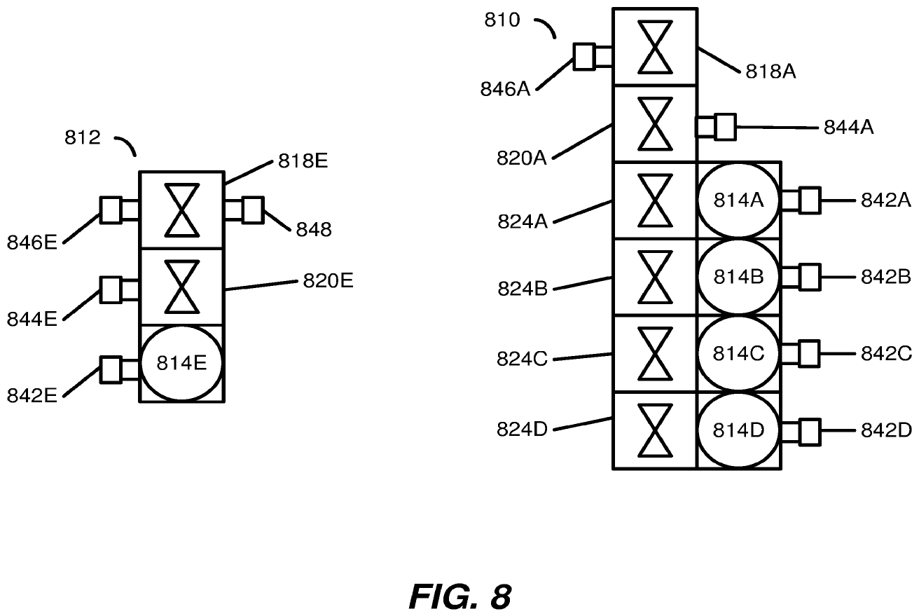

FIG. 8 shows examples of a process gas manifold 810 and an inhibition gas manifold 812. As in the example of FIGS. 6A and 6B, in one example, the process gas manifold 810 is the gas manifold in the first gas zone (not shown) and the inhibition gas manifold 812 is the gas manifold in the second gas zone (not shown). In the example shown, the process gas manifold 810 has four charge volumes 814, four charge volume valves 824, a divert gas valve 820A, and an injection gas valve 818A. The six valves, the four charge volume valves 824, the divert gas valve 820A, and the injection gas valve 818A are fluidically connected in series, as shown in the schematic depicted in FIGS. 6A and 6B. As discussed above in FIGS. 6A and 6B, the number of charge volumes 814 in the process gas manifold 810 may vary. In some embodiments, there may be a single charge volume 814. In other embodiments, there may be multiple charge volumes 814. In the example shown in FIG. 8, there are four charge volumes 814. The charge volumes 814 are parallel to each other and are each fluidically connected to the injection gas valve 818 by their corresponding charge volume valve 824. Each charge volume 814 has a charge volume port 842 that connects to an outside gas source (not shown). The charge volume 814 stores and pressurizes gas from the outside gas source. This allows control of the mass flow of the gas when the gas is released from the charge volume 814. Depending on the application, each charge volume 814 may vary in size. The size of each charge volume 814 depends on different factors, for example, the type of gas being charged in the volume, the volume of gas used for the application, and the pressure used for the application. In some embodiments, each charge volume 814 on the process gas manifold 810 may have the same size. In other embodiments, the size of each charge volume 814 will vary. For example, in a particular process gas manifold 810, three of the four charge volumes have a volume of 0.3 liters and the fourth charge volume has a volume of 0.1 liters. In another example, a process gas manifold 810 has four charge volumes 814, with each charge volume having a volume of 0.3 liters. In some embodiments, the apparatus can be reconfigured to use charge volumes of different sizes depending on the particular process.

Each of the charge volumes 814 is fluidically connected to the injection gas valve 818A via a corresponding charge volume valve 824. The corresponding charge volume valve 824 is fluidically interposed between the injection gas valve 818A and their corresponding charge volume 814. When a charge volume valve 824 is closed, the gas flow from the corresponding charge volume 814 stops and is prevented from reaching the injection gas valve 818A. Gas flows into the charge volume 814 and pressurizes. When the charge volume valve 824 is put in the open position, the gas in the charge volume is released and flows through the process gas manifold 810.

Fluidically interposed between the charge volume valves 824 and the injection gas valve 818A is the divert gas valve 820A. The divert gas valve 820A has a divert gas valve port 844A to connect to a divert gas manifold (not shown). The divert gas valve 820A directs the flow of gas from a charge volume 814 to either the injection gas valve 818A or the divert gas valve port 844A. In some embodiments, the divert gas valve 820A may be three-way valve that can stop the flow of gas.

The injection gas valve 818A has an injection gas valve outlet 846A that fluidically connects the process gas manifold 810 with a dual inlet chamber (not shown). The injection gas valve 818A controls the flow of gas out of the process gas manifold 810. When the injection gas valve 818A is closed, flow out of the process gas manifold 810 stops. When the injection gas valve is opened, the gas from the process gas manifold flows out to the injection gas valve outlet 846A.

The inhibition gas manifold 812 has an injection gas valve 818E, a divert gas valve 820E, and a charge volume 814E fluidically connected to each other. The divert gas valve 820E is fluidically interposed between the injection gas valve 818E and the charge volume 814E. The charge volume 814E has a charge volume port 842E to connect to a gas source (not shown). The gas source provides the gas to the inhibition gas manifold 812 through the charge volume 814E. In the embodiment shown there is a single charge volume 814E and thus no charge volume valve is used. In some embodiments, there may be multiple charge volumes 814. In this case, each charge volume 814 would be in parallel to each other charge volume and each charge volume would have a corresponding charge volume valve to control the flow from the respective charge volume.

The inhibition gas manifold 812 has a divert gas valve 820E with a divert gas valve port 844E. The divert gas valve port 844E of the divert gas valve 820E fluidically connects to a divert gas manifold (not shown). Similar to the divert gas valve 820 in the process gas manifold 810, the divert gas valve directs the flow of gas from the charge volume 814E to either the injection gas valve 818E or the divert gas valve port 844E. In some embodiments, the divert gas valve 820E may be a three-way valve that can stop the flow of gas.

The injection gas valve 818E in the inhibition gas manifold 812 has an injection gas valve outlet 846E and an injection gas valve inlet 848. The injection gas valve outlet 846E fluidically connects the inhibition gas manifold 812 to the dual inlet chamber (not shown). The injection gas valve inlet 848 connects another gas, such as an inert gas, to the inhibition gas manifold 812. For example, the injection gas valve inlet 848 may be connected to Ar and be used to flow inert gas into the chamber, preventing any other process gas from flowing to the inhibition gas manifold 812. The injection gas valve 818E controls the flow of gas out of the inhibition gas manifold 812. When the injection gas valve 818E is closed, flow out of the inhibition gas manifold 812 stops, when the injection gas valve is opened, the flow of gas flows to the injection gas valve outlet 846E.

### DEPOSITION OF TUNGSTEN FILMS

In some implementations, the methods described herein involve deposition of a tungsten nucleation layer prior to deposition of a bulk layer. In the examples described herein, the nucleation layer may be deposited as the first conformal deposition or to as a seed layer for the first conformal deposition. A nucleation layer is a thin conformal layer that facilitates subsequent deposition of bulk tungsten-containing material thereon. According to various implementations, a nucleation layer may be deposited prior to any fill of the feature and/or at subsequent points during fill of the feature. In some implementations of the method described herein, a nucleation layer is deposited only at the beginning of feature fill and is not necessary at subsequent depositions. As described above, in some embodiments, the conformal Dep1 deposition is a nucleation layer. It may also be a bulk layer deposited on a nucleation layer.

In nucleation layer deposition, pulses of a reducing agent, optional purge gases, and tungsten-containing precursor may be sequentially injected into and purged from the reaction chamber in an ALD sequence. Nucleation layer thickness can depend on the nucleation layer deposition method as well as the desired quality of bulk deposition. In general, nucleation layer thickness is sufficient to support high quality, uniform bulk deposition. Examples may range from 10 Å-100 Å.

The methods described herein are not limited to a particular method of tungsten nucleation layer deposition and include deposition of bulk tungsten film on tungsten nucleation layers formed by any method including PNL, ALD, CVD, and physical vapor deposition (PVD). Moreover, in certain implementations, bulk tungsten may be deposited directly in a feature without use of a nucleation layer. For example, in some implementations, the feature surface and/or an already-deposited under-layer supports bulk tungsten deposition. In some implementations, a bulk tungsten deposition process that does not use a nucleation layer may be performed.

In various implementations, tungsten nucleation layer deposition can involve exposure to a tungsten-containing precursor such as tungsten hexafluoride (WF₆), tungsten hexachloride (WCl₆), and tungsten hexacarbonyl (W(CO)₆). In certain implementations, the tungsten-containing precursor is a halogen-containing compound, such as WF₆. Organo-metallic precursors, and precursors that are free of fluorine such as MDNOW (methylcyclopentadienyl-dicarbonylnitrosyl-tungsten) and EDNOW (ethylcyclopentadienyl-dicarbonylnitrosyl-tungsten) may also be used.

Examples of reducing agents can include boron-containing reducing agents including diborane (B₂H₆) and other boranes, silicon-containing reducing agents including silane (SiH₄) and other silanes, hydrazines, and germanes. In some implementations, pulses of tungsten-containing precursors can be alternated with pulses of one or more reducing agents, e.g., S/W/S/W/B/W, etc., W represents a tungsten-containing precursor, S represents a silicon-containing precursor, and B represents a boron-containing precursor. In some implementations, a separate reducing agent may not be used, e.g., a tungsten-containing precursor may undergo thermal or plasma-assisted decomposition.

According to various implementations, hydrogen may or may not be run in the background. Further, in some implementations, deposition of a tungsten nucleation layer may be followed by one or more treatment operations prior to tungsten bulk deposition. Treating a deposited tungsten nucleation layer to lower resistivity may include pulses of reducing agent and/or tungsten precursor.

### BULK DEPOSITION

Bulk deposition may also involve an ALD process in which a tungsten precursor and a reducing agent are sequentially injected into and purged from a reaction chamber. Hydrogen may be used as the reducing agent rather than a stronger reducing agent like diborane that is used in nucleation layer deposition.

Tungsten bulk deposition can also occur by a CVD process in which a reducing agent and a tungsten-containing precursor are flowed into a deposition chamber to deposit a bulk fill layer in the feature. An inert carrier gas may be used to deliver one or more of the reactant streams, which may or may not be pre-mixed. Unlike ALD processes, this operation generally involves flowing the reactants continuously until the desired amount is deposited. In certain implementations, the CVD operation may take place in multiple stages, with multiple periods of continuous and simultaneous flow of reactants separated by periods of one or more reactant flows diverted.

It should be understood that the tungsten films described herein may include some amount of other compounds, dopants and/or impurities such as nitrogen, carbon, oxygen, boron, phosphorous, sulfur, silicon, germanium and the like, depending on the particular precursors and processes used. The tungsten content in the film may range from 20% to 100% (atomic) tungsten. In many implementations, the films are tungsten-rich, having at least 50% (atomic) tungsten, or even at least about 60%, 75%, 90%, or 99% (atomic) tungsten.

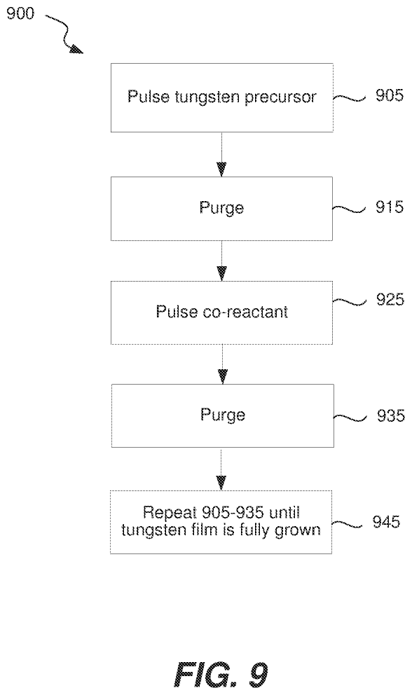

FIG. 9 shows an example of an ALD method of forming a W film. The method according to FIG. 9 may be used, for example, in one or both of operations 202 and 206 of FIG. 2. First, in an operation 905, the W precursor is pulsed. After the W precursor is pulsed, an optional purge 915 may occur. Argon or any inert gas may be used to purge the chamber of any unadsorbed precursor. The substrate is exposed to a co-reactant 925, which may be a reducing agent to reduce the W precursor or other co-reactant to react with the W precursor to form elemental W. The reactant may be a hydrogen-containing reactant. In some embodiments, the hydrogen-containing reactant may be thermal (non-plasma) hydrogen (H₂). For plasma-based process, a remote or in-situ plasma generated from H₂ may be used. An optional purge may be performed at operation 935, followed by repeating operations 905-935 in operation 945 until the film is fully grown. This may be a conformal film lining a feature, such as conformal W film 305 or a bulk layer that fills all or some of the feature such as bulk W 308.

In some embodiments, operation 202 in FIG. 2B-2D includes deposition of W nucleation layer, either as the conformal layer, or as a part of the conformal layer on which bulk W is deposited.

In some embodiments, a W nucleation layer is deposited using one or more of a boron-containing reducing agent (e.g., B₂H₆) or a silicon-containing reducing agent (e.g., SiH₄) as a co-reactant. For example, one or more S/W cycles, where S/W refers to a pulse of silane followed by a pulse of a W-containing precursor, may be employed to deposit a W nucleation layer on which a bulk W layer is deposited. In another example, one or more B/W cycles, where B/W refers to a pulse of diborane followed by a pulse of a W-containing precursor, may be employed to deposit a W nucleation layer on which a bulk W layer is deposited. B/W and S/W cycles may both be used to deposit a W nucleation layer, e.g., x(B/W)+y(S/W), with x and y being integers. Examples of B- and S-containing reducing agents are given below. For deposition of a W nucleation layers, in some embodiments, the W-containing precursor may be a non-oxygen containing precursor, e.g., WF₆ or WCl₅. Oxygen in oxygen-containing precursors may react with a silicon-or boron-containing reducing agent to form WSiₓO_{y} or WBₓO_{y}, which are impure, high resistivity films. Oxygen-containing precursors may be used with oxygen incorporation minimized. In some embodiments, H₂ may be used as a reducing gas instead of a boron-containing or silicon-containing reducing gas. Example thicknesses for deposition of a W nucleation layer range from 5 Å to 30 Å. Films at the lower end of this range may not be continuous; however, as long as they can help initiate continuous bulk W growth, the thickness may be sufficient. In some embodiments, the reducing agent pulses may be done at lower substrate temperatures than the W precursor pulses. For example, or B₂H₆ or a SiH₄ (or other boron-or silicon-containing reducing agent) pulse may be performed at a temperature below 300 °C, with the W pulse at temperatures greater than 300 °C.

While the description below focuses on tungsten feature fill, aspects of the disclosure may also be implemented in filling features with other materials. For example, the treatment sequence described in FIG. 2A-2D may be implemented with feature fill processes that use molybdenum, cobalt, or ruthenium-containing materials.

### APPARATUS

Any suitable chamber may be used to implement the disclosed embodiments. Example deposition apparatuses include various systems, e.g., ALTUS® and ALTUS® Max, available from Lam Research Corp., of Fremont, California, or any of a variety of other commercially available processing systems.

In some embodiments, a first deposition may be performed at a first station that is one of two, five, or even more deposition stations positioned within a single deposition chamber. Thus, for example, hydrogen (H₂) and tungsten hexafluoride (WF₆) may be introduced in alternating pulses to the surface of the semiconductor substrate, at the first station, using an individual gas supply system that creates a localized atmosphere at the substrate surface. Another station may be used for NF₃ treatment with H₂ booster gas, and a third and/or fourth for subsequent ALD bulk fill.

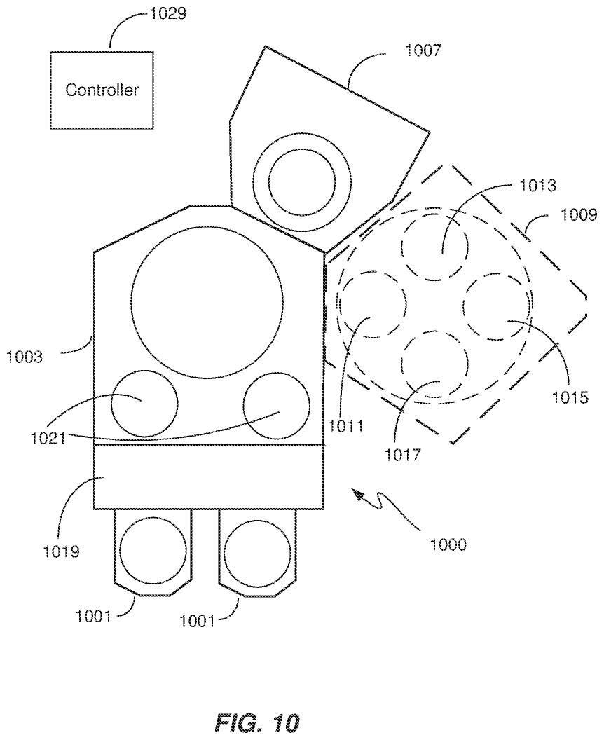

FIG. 10 is a schematic of a process system suitable for conducting deposition processes in accordance with embodiments. The system 1000 includes a transfer module 1003. The transfer module 1003 provides a clean, pressurized environment to minimize risk of contamination of substrates being processed as they are moved between various reactor modules. Mounted on the transfer module 1003 is a multi-station reactor 1009 capable of performing ALD, treatment, and CVD according to various embodiments. Multi-station reactor 1009 may include multiple stations 1011, 1013, 1015, and 1017 that may sequentially perform operations in accordance with disclosed embodiments. For example, multi-station reactor 1009 may be configured such that station 1011 performs a tungsten nucleation layer deposition using a tungsten precursor and a boron-or silicon-containing reducing agent, station 1013 performs an ALD tungsten bulk deposition of a conformal layer using H₂ as reducing agent, station 1015 performs a NF₃ treatment operation, and station 1017 may perform a bulk ALD fill after treatment using H₂ as a reducing agent.

Stations may include a heated pedestal or substrate support, one or more gas inlets or showerhead or dispersion plate.

Returning to FIG. 10, also mounted on the transfer module 1003 may be one or more single or multi-station modules 1007 capable of performing plasma or chemical (non-plasma) pre-cleans, other deposition operations, or etch operations. The module may also be used for various treatments to, for example, prepare a substrate for a deposition process. The system 1000 also includes one or more wafer source modules 1000, where wafers are stored before and after processing. An atmospheric robot (not shown) in the atmospheric transfer chamber 1019 may first remove wafers from the source modules 1001 to loadlocks 1021. A wafer transfer device (generally a robot arm unit) in the transfer module 1003 moves the wafers from loadlocks 1021 to and among the modules mounted on the transfer module 1003.

In various embodiments, a system controller 1029 is employed to control process conditions during deposition. The controller 1029 will typically include one or more memory devices and one or more processors. A processor may include a CPU or computer, analog and/or digital input/output connections, stepper motor controller boards, etc.

The controller 1029 may control all of the activities of the deposition apparatus. The system controller 1029 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 1029 may be employed in some embodiments.

Typically there will be a user interface associated with the controller 1029. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general-purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 1029. The signals for controlling the process are output on the analog and digital output connections of the deposition apparatus 1000.

The system software may be designed or configured in many different ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller 1029 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 1029, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 1029, in some implementations, may be a part of or coupled to a computer that is integrated with, coupled to the system, otherwise networked to the system, or a combination thereof. For example, the controller 1029 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller 1029 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method comprising:
providing a 3-D structure of a partially manufactured semiconductor substrate to a chamber having a chamber pressure of no more than 100 Torr, the 3-D structure comprising sidewalls, a plurality of openings in the sidewalls leading to a plurality of features having a plurality of interior regions fluidically accessible through the openings to a chamber;
depositing a first layer of tungsten within the 3-D structure such that the first layer lines the plurality of features of the 3-D structure; and
treating the first layer of tungsten non-conformally with a treatment such that that the treatment is preferentially applied at portions of the first layer of tungsten near the plurality of openings relative to the plurality of interior regions;
introducing a booster gas comprising H₂ to the chamber; and
depositing a second layer of tungsten within the 3-D structure on the first layer of tungsten such that the second layer at least partially fills the plurality of interior regions of the 3-D structure, wherein treating the first layer of tungsten non-conformally comprises charging a gas comprising NF₃ to a first charge pressure of least 10 Torr and flowing the gas to the chamber.

2. The method of claim 1, wherein the booster gas further comprises argon.

3. The method of claim 1, wherein the booster gas further comprises nitrogen.

4. The method of claim 1, wherein the booster gas is introduced during the treating of the first layer of tungsten.

5. The method of claim 1, wherein the booster gas is introduced before the treating of the first layer of tungsten and after depositing the first layer of tungsten.

6. The method of claim 1, wherein the booster gas is introduced after the treating of the first layer of tungsten and before depositing the second layer of tungsten.

7. The method of claim 1, further comprising depositing a nucleation layer within the 3-D structure such that nucleation layer lines the plurality of features of the 3-D structure, wherein the booster gas is introduced before the treating of the first layer of tungsten, before depositing the first layer of tungsten, and after depositing the nucleation layer.

8. The method of-any claim 1, wherein the treatment inhibits tungsten deposition.

9. The method of claim 1, wherein depositing a layer of tungsten comprises an atomic layer deposition using tungsten hexafluoride (WF₆) and hydrogen (H₂).

10. The method of claim 1, wherein depositing a layer of tungsten comprises delivering pulses of a tungsten precursor and hydrogen to the chamber via a showerhead.

11. The method of-any claim 1, wherein depositing tungsten comprises delivering a tungsten precursor and hydrogen to a showerhead via a dual inlet chamber.

12. The method of claim 11, wherein the tungsten precursor and hydrogen are injected at a first inlet of the dual inlet chamber.

13. The method of claim 12, wherein the gas comprising NF₃ is injected at a second inlet of the dual inlet chamber.

14. The method of claim 13, wherein an inert gas is injected in the first inlet of the dual inlet chamber while the NF₃ is injected at the second inlet of the dual inlet chamber.

15. The method of claim 11, wherein the tungsten precursor and hydrogen gas are supplied through a first gas manifold and the NF₃ is supplied through a second gas manifold.

16. The method of claim 7, wherein depositing the nucleation layer takes place at a first station in the chamber and the deposition of the first layer of tungsten, the treatment, and the deposition of the second layer of tungsten takes place in a second station in the chamber.

17. An apparatus for semiconductor processing, the apparatus comprising:
a first showerhead;
a dual inlet chamber having
a first inlet,
a second inlet, and
an outlet fluidly connected to the first showerhead;
a first gas zone comprising a first process gas manifold, the first process gas manifold comprising:
one or more first process gas charge volumes,
a first divert valve fluidically connected to the one or more first process gas charge volumes, and
a first injection process gas valve fluidically connected to the first divert valve,
wherein the first process gas manifold is configured to be fluidically connected to one or more first process gas sources via the one or more first process gas charge volumes; and
wherein the first process gas manifold, via the first injection process gas valve, is fluidically connected to the first inlet of the dual inlet chamber;
a second gas zone comprising a second process gas manifold, the second process gas manifold comprising:
one or more second process gas charge volumes,
a second divert valve fluidically connected to the one or more second process gas charge volumes, and
a second injection process gas valve fluidically connected to the second divert valve,
wherein the second process gas manifold is configured to be fluidically connected to one or more second process gas sources via the one or more second process gas charge volumes, and
wherein the second process gas manifold, via the second injection process gas valve, is fluidically connected to the second inlet of the dual inlet chamber;
a top plate divert manifold,
wherein the top plate divert manifold is fluidically connected to the first process gas manifold via the first divert process gas valve; and
a gas box divert manifold,
wherein the gas box divert manifold is fluidically connected to the second process gas manifold via the second divert process gas valve,
wherein the first gas zone is separate from the second gas zone upstream of the dual inlet chamber.

18. The apparatus of claim 17, further comprising:
a multi-station chamber having a first station comprising the first showerhead and one or more additional stations, each comprising a showerhead.

19. The apparatus of claim 18, wherein at least one station of the multi-station chamber is fluidically connected to no more than one gas zone.

20. The apparatus of claim 17, wherein the dual inlet chamber comprises an annulus surrounding a main line connected to the outlet.

21. The apparatus of claim 20, wherein the second inlet is at a side of the annulus.
